(19) United States
(12) Patent Application Publication
(10) Pub. No.: US 2017/0254704 A1
(43) Pub. Date: Sep. 7, 2017

(54) THERMAL PATTERN SENSOR WITH BOLOMETERS UNDER CAPSULE(S)

(71) Applicant: Commissariat A L'Energie Atomique et aux Energies Alternatives, Paris (FR)

(72) Inventors: Sebastien BECKER, Voiron (FR); Jean-Francois MAINGUET, Grenoble (FR)

(73) Assignee: Commissariat A L'Energie Atomique et aux Energies Alternatives, Paris (FR)

(21) Appl. No.: 15/445,235

(22) Filed: Feb. 28, 2017

(30) Foreign Application Priority Data
Mar. 1, 2016 (FR) 16 51705

(51) Int. Cl. G01J 5/20; H01L 27/146

(52) U.S. Cl. CPC G01J 5/20; H01L 27/14621

(57) ABSTRACT

A sensor of thermal patterns of an object, of papillary print sensor type, including a contact surface to apply the object thereon. The sensor includes at least one capsule sealed under vacuum, arranged between a substrate and the contact surface, suited to exchanging heat with the object and to emitting electromagnetic radiation as a function of its temperature; inside each capsule, at least one bolometric plate, to convert incident electromagnetic radiation into heat; at least one optical filter, to stop electromagnetic radiation in the infrared, each capsule being covered by an optical filter; with reading the electrical resistances of the bolometric plates. Such a print sensor offers both good insulation between the substrate and the sensitive elements, and good mechanical strength.

### TECHNICAL FIELD

The invention relates to the field of thermal pattern sensors or detectors, or sensors of the thermal print of an object, for imaging the thermal patterns of an object, designated object to image.

Such sensors measure a two-dimensional distribution of the thermal mass of an object with which they are in direct physical contact, and even its thermal capacity and/or its thermal conductivity.

They form transducers of a temporal variation in temperature, into a difference in potentials or currents.

Such a sensor may form a mass spectrometer type analysis apparatus, or flowmeter (by heating the object at one spot and measuring up to where the heat propagates). It may form in particular measuring means at various depths in an object, by varying the power injected to heat the object, and the measuring times.

It may also form a papillary print sensor, for imaging a print linked to the particular folds of the skin, in particular a finger print, but also a palm, plantar, phalanx print. These various prints are together designated by the term papillary prints.

Such a papillary print sensor uses a difference in thermal impact, on a contact surface, between regions in direct physical contact with the finger, at the level of the ridges of the print, and regions not in direct physical contact with the finger, at the level of the valleys of the print.

### PRIOR ART

Different types of sensors of thermal patterns, in particular sensors of a papillary print, are known in the prior art.

Sensors based on the pyroelectrical properties of a material such as PVDF are for example known. Such a material only however measures variations in temperature as a function of time. After a very short time interval, the temperatures stabilise and the image obtained is insufficiently contrasted.

Sensors based on the thermoresistive properties of a material, the resistance of which is temperature dependent, are also known.

When someone places his finger on the sensor, the contact with the finger heats the thermoresistive material. The temperature of the thermoresistive material varies, depending on whether it is covered by a region of the finger corresponding to a ridge of the finger print, or to a valley of the finger print. It is thus possible to form an image of the finger print.

The document U.S. Pat. No. 6,633,656 describes an example of such a sensor. The thermoresistive material is vanadium oxide (VOₓ). It is deposited in the form of a pixelated layer, directly on a substrate, or insulated therefrom by a layer of an insulator material.

Despite the potential presence of the insulating material, heat is transmitted rapidly from the VOₓ layer to the substrate, which adversely affects the contrast of the image obtained.

The finger print sensor described in the article of Ji-Song Han, “Thermal Analysis of Fingerprint Sensor Having a Microheater Array”, International Symposium on Micromechatronics and Human Science, 1999 IEEE is also known.

In this article, the authors study the characteristics of a thermal sensor in which each pixel consists of a silicon rod.

The silicon rod has a central region, forming the sensitive zone of a pixel of the sensor, framed by two lateral regions receiving electrodes.

The silicon rod is heated, the detection exploiting the properties of heat transmission between the silicon rod and the skin.

The sensitive zone of the silicon rod is also framed by two cavities, etched in the substrate. These two cavities join together under the sensitive zone, and improve the thermal insulation between the silicon rod and the substrate.

A drawback of this embodiment is in particular that the surface fill rate of the sensitive elements, here the central regions of the silicon rods, is limited in particular by the lateral size of the etched cavities.

An objective of the present invention is to propose a sensor of thermal patterns, such as a papillary print, having both optimised thermal insulation between the sensitive elements and a substrate, and a high filling rate of the sensitive elements.

### DESCRIPTION OF THE INVENTION

This objective is attained with a sensor of thermal patterns of an object, in particular a papillary print, comprising a contact surface to apply the object to image thereon.

According to the invention, the sensor comprises:

at least one capsule sealed under vacuum, arranged between a substrate and said contact surface, suited to exchanging heat by conduction with the object to image and to emitting electromagnetic radiation as a function of the temperature of the capsule;

inside each capsule sealed under vacuum, at least one bolometric plate, suited to converting incident electromagnetic radiation coming from the capsule into heat;

at least one optical filter, to stop electromagnetic radiation in the infrared, each capsule being covered by an optical filter; and

means of reading the electrical resistances of the bolometric plates.

The bolometric plates form the sensitive elements of the sensor according to the invention.

In operation, the user places an object in direct physical contact with the contact surface of the sensor according to the invention.

Heat transfer takes place between the capsule(s), situated under the contact surface, and the object.

The term heat exchange is also used to designate heat transfer. The direction of heat transfer depends on the respective temperatures of the skin and the capsules, the heat going from the hottest element to the coldest element.

The internal faces of each capsule emit electromagnetic radiation in the direction of the bolometric plates.

The power of this electromagnetic radiation is directly linked to the temperature of the capsule, itself linked to the heat exchange with the object.

Each bolometric plate thus receives electromagnetic radiation, the power of which depends on the local temperature of the object, above said plate.

The incident electromagnetic radiation on a bolometric plate is absorbed by it, and modifies its temperature.

The electrical resistance of the bolometric plate depends on its temperature. Thus, the new temperature of the bolometric plate defines a new electrical resistance of the bolometric plate, read by means of reading the electrical resistances of the bolometric plates.

The means of reading the electrical resistances of the bolometric plates may measure in particular, for each bolometric plate, a variation in electrical resistance induced by the variation in the incident electromagnetic flux absorbed, this variation being induced by the local heat exchange between the capsule and the object.

It is thus possible to obtain a two-dimensional distribution of the heat transfers between the object and the sensor, and thus the thermal mass of the object.

The two-dimensional distribution of the values of the electrical resistances of the bolometric plates constitutes a thermal image of the object.

In the particular case of a papillary print sensor, the user for example places his finger, or his hand, on the print sensor according to the invention.

At the level of the ridges of the print, the skin is in direct physical contact with the contact surface of the sensor, such that heat transfer between the capsule(s) and the skin takes place by conduction.

At the level of the valleys of the print, the skin in not in direct physical contact with the contact surface of the sensor, such that heat transfer between the capsule(s) and the skin at best takes place by convection.

Consequently, the variation in temperature at the level of the capsules is greater at the level of the ridges of the print than at the level of the valleys of the print.

This results in a different value of the new electrical resistance of the bolometric plate, depending on whether said plate is located under a ridge or under a valley of the print. An image of this print is obtained from the measurements of electrical resistances of the bolometric plates.

One of the ideas on which the invention is based, consists, moreover, in observing that when the contact surface is not hidden by the object to image, the exterior environment generally comprises radiating bodies which emit electromagnetic radiation in the infrared.

Yet, the capsules(s) is/are transparent in the infrared, such that this radiation can reach the bolometric plates and affect their electrical resistances.

It may be difficult, in particular, to distinguish an image of the object, corresponding to an object actually in direct physical contact with the sensor, from a non-relevant image acquired when the object approaches the contact surface but without yet being in direct physical contact therewith.

To overcome this difficulty, the invention proposes a clever solution, by covering each capsule(s) with an optical filter to stop electromagnetic radiation in the infrared. Thus, the electromagnetic radiation emitted by the finger or the hand does not traverse the capsules. When the object to image is not in direct contact with the contact surface of the sensor, the bolometric plates all receive a same infrared flux which corresponds to that which is emitted by the internal face of a capsule, at equilibrium temperature. All the bolometric plates then receive a same infrared flux, independently of the external conditions. The object may only be imaged when it is in direct contact with the contact surface of the sensor, when heat transfers take place between object and the at least one capsule.

It is evidently understood that, according to the invention, each bolometric plate is thus advantageously covered by an optical filter.

The sensitive elements, consisting of bolometric plates, are suspended above the substrate, thermally insulated therefrom by a vacuum inside the capsule.

Each bolometric plate is arranged inside a capsule, which protects it from external mechanical stresses. Thus, the sensor according to the invention offers both good insulation between the substrate and the sensitive elements, and good mechanical strength.

In operation, the object to image is applied not directly on the bolometric plates, but on the contact surface above the capsule(s), such that the bolometric plates are protected from compressive stresses exerted by the object.

Since it is the capsule that ensures the mechanical strength of the sensor, the bolometric plates may be simply vertically supported on legs of reduced diameter, above the substrate.

Consequently, the surface fill rate by the bolometric plates is not limited by the presence of wide supports on either side of each bolometric plate. Despite the occupancy rate of the side walls of the capsules, it is possible to obtain a very good surface fill rate by the bolometric plates.

According to the invention, each capsule is covered by an optical filter. This does not necessarily imply that each optical filter covers a single capsule. According to the invention, each optical filter thus extends above at least one capsule.

### BRIEF DESCRIPTION OF THE DRAWINGS

The present invention will be better understood on reading the description of exemplary embodiments given for purely illustrative purposes and in no way limiting, and by referring to the appended drawings in which:

FIG. 1 illustrates a first embodiment of a print sensor according to the invention, according to a sectional view;

FIG. 2 illustrates a second embodiment of a print sensor according to the invention, according to a sectional view;

FIG. 3 illustrates a third embodiment of a print sensor according to the invention, according to a sectional view;

FIG. 4 illustrates a fourth embodiment of a print sensor according to the invention, according to a sectional view;

FIG. 5 illustrates a fifth embodiment of a print sensor according to the invention, according to a sectional view;

FIG. 6 illustrates a sixth embodiment of a print sensor according to the invention, according to a sectional view;

FIGS. 7A and 7B illustrate a seventh embodiment of a print sensor according to the invention, and a method of using such a sensor; and

FIGS. 8A and 8B illustrate an eighth embodiment of a print sensor according to the invention, and a method of using such a sensor.

### DETAILED DESCRIPTION OF PARTICULAR EMBODIMENTS

Hereafter, but in a non-limiting manner, a sensor according to the invention of finger print sensor type is more particularly described.

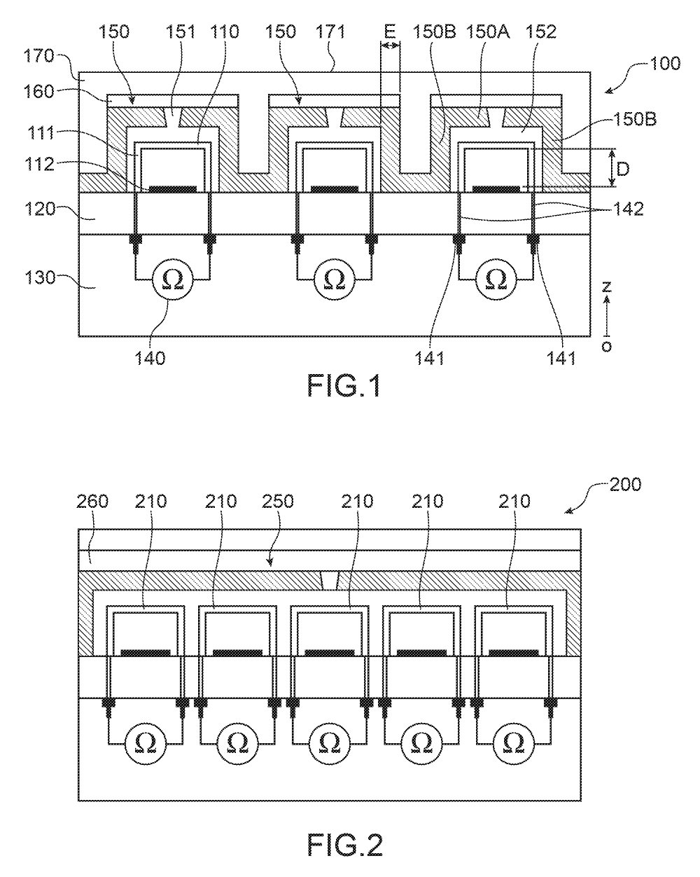

FIG. 1 illustrates in a schematic manner a first embodiment of a finger print sensor 100 according to the invention, according to a sectional view.

The print sensor 100 is of matrix type, that is to say consists of a plurality of sensitive elements, distributed for example in lines and columns.

These sensitive elements are arranged above a substrate 130, here covered by an intermediate layer 120.

The substrate 130 is for example a substrate compatible with CMOS (Complementary Metal Oxide Semiconductor) technology, in particular silicon. This variant is particularly suited to a finger print sensor, in which the sensitive elements are distributed according to a matrix of several mm or cm sides, for example 8*8 mm², up to 2*3 cm².

In a variant, the substrate 130 may be a substrate compatible with TFT (Thin Film Transistor) technology, in particular glass. This variant is particularly suited to a palm print sensor, in which the sensitive elements are distributed according to a matrix of large dimensions.

Each sensitive element here consists of a bolometric plate 110, bearing on support legs 111 above the substrate 130.

The bolometric plate 110 comprises an absorption membrane, and a thermoresistive layer which may be merged with the absorption membrane, or in direct contact therewith, preferably over its whole surface.

The absorption membrane is intended to convert into heat the energy of incident electromagnetic radiation, in particular radiation in the mid infrared, at a wavelength comprised between 3 and 50 μm, and more particularly around 10 μm, for example between 5 and 20 μm or between 8 and 14 μm.

The absorbed energy heats the thermoresistive layer.

The thermoresistive layer has an electrical resistivity that is temperature dependent. For each bolometric plate, an electrical resistance is thus measured which varies as a function of its temperature.

In particular, these two quantities may be linked by:

R(T₀+θ)=R(T₀)*e^{TCR}*^{θ}

with T₀ the initial temperature, θ the variation in temperature, and TCR the thermal coefficient of resistance of the thermoresistive layer.

The thermoresistive layer may be made of vanadium oxide, amorphous silicon, titanium oxide, nickel oxide, or any other material exhibiting a variation in resistivity as a function of temperature.

The absorption membrane may be made of titanium nitride.

The bolometric plate 110 is suspended above a reflector 112, suited to reflecting to the bolometric plate part of the incident electromagnetic radiation having traversed same. Thus, the reflector 112 reflects electromagnetic radiation in the infrared, which traverses the bolometric plate 110 without being directly absorbed.

This reflector 112, typically made of metal, also serves as shielding, by forming a Faraday cage. It may be electrically connected to the ground, or any other fixed potential. It may also form a protection with regard to electrostatic discharges.

The reflector 112 is for example a thin metal layer of copper or aluminium, typically of 100 nm thickness, arranged between the substrate 130 and the bolometric plate, here deposited directly on the intermediate layer 120.

The distance D between the bolometric plate 110 and the reflector 112 is equal to around λ/4, where λ is the central wavelength of absorption by the bolometric plate. For example λ=10 μm and D=2.5 μm. The reflector 112 and the bolometric plate 110 thus form a quarter wave cavity, realising an additive interaction between the wave transmitted through the bolometric plate 110 and the wave reflected on the reflector 112, to maximise the quantity of energy absorbed by the bolometric plate.

The substrate 130 receives a circuit for reading the electrical resistance of each bolometric plate, and more particularly each thermoresistive layer. Each bolometric plate is electrically connected to two first connection pads 141 flush with the surface of the substrate, through two vias 142 which pass through the intermediate layer 120. The two first connection pads are connected to means 140 of reading an electrical resistance, symbolised in the figures by an ohmmeter.

The first connection pads 141 are made of metal, in particular copper or aluminium.

The reading of the electrical resistance implements a current, respectively voltage polarisation of the bolometric plate, and a voltage, respectively current, measurement.

The bolometric plate will not be described further herein because it is an element known per se in the field of infrared detection.

Each bolometric plate is suspended in a vacuum, inside a capsule 150.

Vacuum means here a gaseous medium rarefied in gas, having a pressure less than 10⁻³ m bars.

In the example represented in FIG. 1, each capsule 150 encompasses a single bolometric plate 110.

The capsules are three-dimensional structures, hermetically closed and placed under vacuum during a sealing process.

Each capsule 150 has a cap shape surrounding a cavity 152. The cap consists of side walls 150B, topped by an upper wall 150A.

Throughout the text, the term “upper” and “lower” refer to a vertical axis (Oz), orthogonal to the substrate, and oriented from the substrate to the capsules.

In the example represented in FIG. 1, the capsule cooperates with a lower layer on which it rests, here the intermediate layer 120, to define the cavity 152, forming a closed volume sealed under vacuum.

The upper wall 150A is pierced by at least one orifice 151 or hole, making it possible to remove a sacrificial layer used to manufacture the capsule. This orifice 151 is hermetically closed by a layer covering the capsules.

In the figures, the orifice 151 is represented at the centre of the upper wall 150A. The orifice may however be positioned elsewhere on the capsule. There may also be several orifices per capsule.

According to a preferred embodiment, the side walls 150B extend substantially vertically, parallel to the axis (Oz). They have a constant height along (Oz). The upper wall 150A is a flat wall, which extends in a horizontal plane, orthogonal to the axis (Oz). It is in direct physical contact, over its whole perimeter, with the upper edges of the side walls 150B.

The upper wall 150A here has a square shape, the side walls have a square base cylinder shape, and the capsule surrounds a rectangular parallelepiped shaped cavity 152.

Each cavity 152 may enclose a getter material, to conserve the quality of the vacuum over time. A getter material, or gas trap, limits the appearance of gas in an enclosure. It may be an easily oxidisable metal such as titanium, or vanadium, zirconium, cobalt, iron, manganese, aluminium or an alloy of these metals.

In the example illustrated in FIG. 1, all the capsules are formed in one piece, connected together on the lower side of their respective side walls, by peripheral regions that extend directly onto the substrate.

Thanks to the vacuum inside the capsules, the bolometric plates 110 do not exchange heat with their surrounding environment by conduction or convection. They are thus only sensitive to incident infrared radiation, here emitted by the internal faces of the capsules 150.

In order to further limit potential heat exchanges other than by radiation between the bolometric plates and their environment, the support legs 111 on which the bolometric plates rest occupy less than a tenth of the surface of the bolometric plates. The support legs 111, or plugs, preferably have only several hundreds of nanometres diameter.

Moreover, the vacuum under the capsules thermally insulates the substrate and the upper walls 150A of the capsules. Heat transfers involving the capsules and not involving the object applied on the contact surface are thus limited.

In the example represented in FIG. 1, the capsules rest on an intermediate layer 120.

The intermediate layer 120 is a barrier layer, forming a barrier to the etching of a sacrificial layer, the sacrificial layer being deposited during the process of manufacturing the capsules and/or during the process of manufacturing the suspended bolometric plates.

The intermediate layer 120 is for example made of SiC, AlN, Al₂O₃, SiN, SiO, SiON, SiC, etc.

It may also have thermal insulating properties, to improve the thermal insulation between the substrate and the capsules. It may have low thermal conductivity, for example less than 5 W·m⁻¹·K⁻¹, and even less than 2 W·m⁻¹·K⁻¹, or even than 1 W·m⁻¹·K⁻¹.

The layer 120 is optional, in particular when the substrate is made of glass.

According to a variant not represented, the substrate is separated from the capsules by two layers, one dedicated more specifically to the thermal insulation of the capsules, the other dedicated more specifically to stopping the etching of the sacrificial layer.

The capsules 150 are advantageously in direct contact with the intermediate layer 120.

If need be, a thin tie layer may be deposited on the intermediate layer.

The thin tie layer comprises for example titanium or tantalum, for example TiN, Ti/TiN, TaN, or Ta/TaN.

In variants in which the capsules are heated (through metal optical filters, see hereafter), it may be advantageous to ensure that the thin tie layer does not short-circuit the capsules (choice of an electrically insulating tie layer, or suitable texturing thereof to avoid passing above connection pads).

The capsules are for example made of amorphous silicon (a-Si), in particular hydrogenated amorphous silicon (a-Si:H), which can be doped, for example by atoms of boron or germanium. This material has in particular good mechanical resistance. Moreover, it is a conforming material meaning that the large geometric discontinuities linked to the capsule shape do not imply electrical discontinuity. It is compatible with standard TFT and CMOS technologies.

In a variant, the amorphous silicon is mixed with another component within an alloy. It is possible to use for example hydrogenated amorphous silicon (a-Si:H), for example a-SiₓGe_{y}B_{z}:H, in particular a-SiGe:H or a-SiGeB:H.

Each capsule is covered with a dedicated optical filter, or a portion of an optical filter covering several capsules.

Here, each optical filter 160 covers the upper wall 150A of a single capsule 150.

Thus, and as illustrated in FIG. 1, each bolometric plate 110 is covered, or topped, by an optical filter 160.

Each optical filter 160 is an infrared optical filter.

It has the properties of infrared filter and heat conductor.

It stops electromagnetic radiation capable of heating the bolometric plates if it could traverse the capsules, in particular radiation in the mid infrared, at a wavelength comprised between 5 and 20 μm, and more particularly between 8 and 14 μm.

It may be for example a reflector, which reflects electromagnetic radiation towards the exterior of the print sensor 100.

On the other hand, the infrared filter 160 transmits by conduction heat transmitted by a body in contact therewith.

It is formed for example by a metal layer 160.

The function of infrared filtering and heat conduction may also be achieved by a non-metal material.

The infrared filter 160 is for example made of titanium, aluminium, platinum, nickel, or, copper, titanium nitride (TiN), or an alloy such as Ti/TiN or Ti/Al.

The infrared filter 160 may have a coefficient of reflection greater than 70% at 10 μm, and good thermal conductivity, for example at least 20 W·m⁻¹·K⁻¹ at 20° C. at atmospheric pressure.

It has preferably mismatched impedance relative to the impedance of a vacuum inside the capsules.

For example, the bolometric plates are suspended in a vacuum, of 377Ω impedance, and the infrared filter has an impedance less than 5Ω. Absorption by the filter of infrared radiation incident thereon is thus limited. This thus avoids infrared radiation heating the filter.

The infrared filter 160 may also make it possible to close the orifices 151, for example to hermetically close the capsules under vacuum.

In a variant, the orifices 151 are closed by a layer separate from the infrared filter, for example a layer of germanium, and the optical filter extends onto this separate layer.

The infrared filters 160 are covered with a protective layer 170, to protect the capsules with regard to repeated contacts with human tissues.

An outer face of the protective layer 170, above the capsules, forms a contact surface 171 of the print sensor.

The thickness and the thermal conductivity of the protective layer are suited to ensuring both good heat transfer between the finger and the capsules and limiting lateral diffusion of heat.

The protective layer may consist of a thick oxide layer, an epoxy polymer (epoxy paint) layer, an amorphous carbon layer, designated DLC (Diamond-Like Carbon), etc.

It has advantageously a thickness less than 30 μm, and even less than 20 μm, or even less than 1 μm for the DLC.

In a variant, a layer forming an infrared filter also has a protective function with regard to repeated contacts with human tissues, which makes it possible to do away with a specific protective layer.

In operation, the user moves his finger towards the contact surface 171. The finger emits electromagnetic radiation, which is stopped by the infrared filter 160.

When the finger is laid on the finger print sensor, in direct physical contact with the contact surface 171, the skin is then in direct contact with the contact surface 171, at the level of the ridges of the finger print, where heat exchange takes place with the capsules 150, through the infrared filter 160.

This heat exchange leads to a variation in the temperature of the capsules, and thus a modification of the power of electromagnetic radiation in the infrared, emitted towards the inside of the capsules and in the direction of the bolometric plates.

This modification of the electromagnetic radiation leads in its turn to a modification of the temperature of the bolometric plates, and thus their electrical resistances.

Thus, the bolometric plates situated under a ridge of the print take a first electrical resistance value, measured by the electrical resistance reading means 140.

At the level of the valleys of the finger print, the absence of direct physical contact leads to a lower heat exchange between the finger and the capsules, which results in a different value of the electrical resistances of the bolometric plates situated below.

Each resistance value of a bolometric plate may be converted into grey levels, by conversion means not represented, to form an image of the finger print.

This type of detection is called “passive thermal detection”.

Preferably, it is used jointly with a sweeping of the finger over the contact surface 171, to delay the appearance of a thermal equilibrium at the level of the capsules, leading to a drop in contrast of the image of the print.

The walls 150A and 150B of the capsules 150 may have a thickness E of around 1 μm, for example comprised between 0.5 and 2 μm, which suffices to confer good mechanical resistance to the capsule.

Such capsules have high mechanical stability, in particular with regard to pressure stresses that can be exerted when a user presses his finger on the contact surface of the sensor.

The distance between the upper wall 150A of the capsule, and the bolometric plate, may be less than 2 μm, and even 1 μm, for example comprised between 600 and 800 nm. Thus, the efficiency of energy transfer between the capsule and the bolometric plate is optimised.

Each capsule may have reduced dimensions, such that the capsules are distributed according to a reduced repetition step, in particular less than 51 μm, for example 50.8 μm or 25.4 μm. A print sensor having a very good modulation transfer function is also produced.

The capsules may be arranged very close to each other. For example, two neighbouring capsules may be spaced apart by only several hundreds of nanometres.

Moreover, if a capsule is electrically conducting, it forms a shielding against electrostatic parasites, in particular around 50Hz, brought about by contact with the skin when the finger touches the contact surface of the sensor. It thus makes it possible to limit noise injected by capacitive coupling between the skin and the sensitive elements of the sensor.

The bolometric plates define together a detection surface of the print sensor.

Inside each capsule, the bolometric plate may extend over a large surface, such that the sensor may have a good surface fill rate of the detection surface, by the bolometric plates, for example greater than 0.6, or 0.8.

In practice, the print sensor 100 may be produced by means of the following steps:

preferably, deposition on the substrate of the intermediate layer 120, having an etching stop function (to protect the substrate during removal of the sacrificial pads);

construction of the bolometric plates suspended above the intermediate layer 120, by means of a first sacrificial layer, organic (for example polyimide) or mineral (for example silicon oxide), and of removal of this first sacrificial layer;

deposition of a second sacrificial layer covering and embedding the bolometric plates;

local etchings of the second sacrificial layer to form sacrificial pads around the bolometric plates;

deposition of the material of the capsules, on and between the sacrificial pads, to form the matrix of capsules;

local etching of the material of the capsules, to form the orifices 151;

removal of the material of the sacrificial pads, going through the orifices 111;

deposition of the infrared filter 160;

deposition of the protective layer 170.

Those skilled in the art will know if necessary how to find more details on the first steps of the manufacturing method, by referring to the field of infrared detection, see for example document EP 2 466 283.

These methods of the prior art may be called “pixel level packaging”. They do not comprise a step of deposition of an infrared filter. According to these methods, it is sought on the contrary to maximise the transmission level of infrared through the capsules.

Here, the second sacrificial layer is etched everywhere, except at the emplacements intended to form the cavities 152.

The material of the capsules is deposited, at substantially constant thickness, on all of the side and upper surfaces of the sacrificial pads, and between two sacrificial pads.

The first and the second sacrificial layers may be made of organic material. It may be a polymer, in particular an organic polymer such as polyimide. The sacrificial pads can then be removed by oxygen plasma etching.

In particular, it is possible to produce a print sensor compatible with TFT technology, on a glass substrate, by producing the capsules by means of first then second sacrificial polymer layers (for example made of polyimide), later removed by oxygen plasma etching, and by means of PECVD of thermoresistive material.

Preferably, the substrate 130 is protected by the intermediate layer 120 for stopping the etching, resistant to oxygen plasma etching, for example made of SiN, SiO, SiO₂, SiON, SiC, etc.

In a variant, it is possible to do away with an etching stop layer, when a passivation layer, intrinsic to the substrate, is able to protect it and to serve as barrier to oxygen plasma etching. This passivation layer, not represented in the figures, is for example made of SiNₓ or SiOₓ.

In a variant, the first and second sacrificial layers may be made of a mineral material. It may be an oxide, for example silicon oxide. The sacrificial pads may then be removed by HF (hydrofluoric acid) etching.

In this case, it is necessary to protect the substrate 130 by an intermediate layer 120 for stopping the etching.

For a mineral sacrificial layer (for example SiO₂) with HF etching, the layer 120 for stopping the etching may be AlN, Al₂O₃, SiC, amorphous carbon, DLC and potentially polyimide.

The thickness of this layer is comprised between 20 and 200 nm, preferentially 50 nm.

In particular, it is possible to produce a print sensor compatible with CMOS technology, by producing the capsules using first then second sacrificial mineral layers, removed later by HF etching, and by CVD of thermoresistive material.

The document EP 2 743 659 describes, in another context, an example of a method using a sacrificial layer removed later by HF etching.

The material of the capsules may be deposited by chemical vapour deposition (CVD), in particular when the print sensor incorporates CMOS technology, or by plasma enhanced chemical vapour deposition (PECVD), in particular when the print sensor incorporates TFT technology, or by physical vapour deposition (PVD).

FIG. 2 schematically illustrates a second embodiment of print sensor 200 according to the invention.

The embodiment of FIG. 2 will only be described for its differences relative to the embodiment of FIG. 1.

In this second embodiment, a single capsule 250 is sealed under vacuum, enclosing all of the bolometric plates 210 of the print sensor 200.

It may be referred to as a macro-capsule.

This macro-capsule is reinforced locally by pillars that extend between the bolometric plates, to ensure its mechanical stability.

This makes it possible to reduce the space between two bolometric plates, to further increase the fill factor of the detection surface by the sensitive elements of the sensor.

On the other hand, there is important thermal cross talk between the pixels of the sensor, since it is a same and unique upper capsule wall that produces heat exchanges with the object laying on the contact surface.

Here, a single optical filter 260 extends above all the bolometric plates, above the macro-capsule 250.

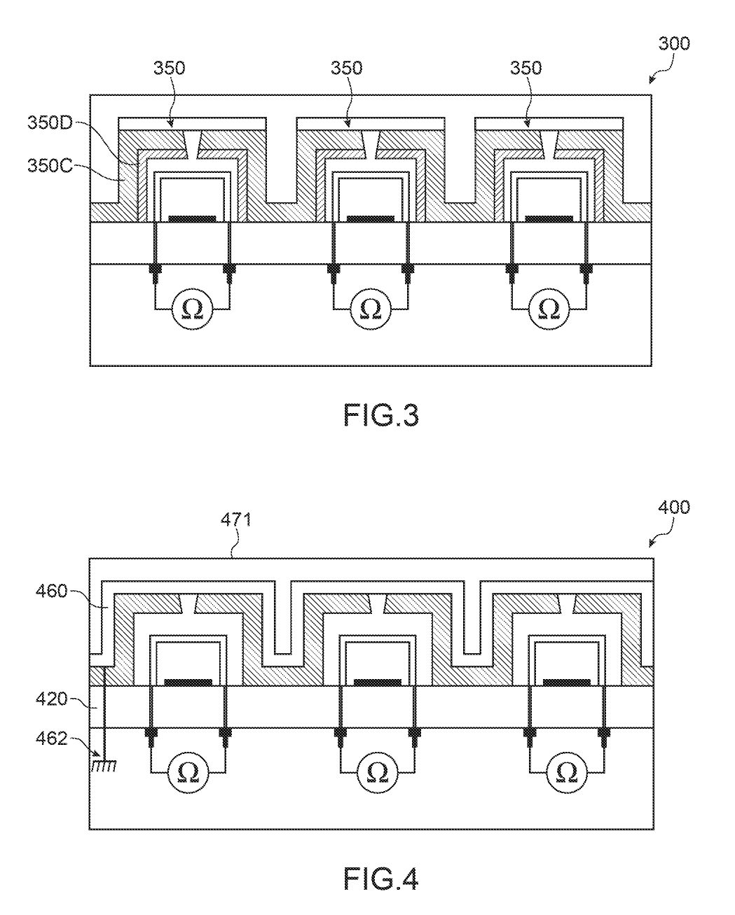

FIG. 3 schematically illustrates a third embodiment of print sensor 300 according to the invention.

The embodiment of FIG. 3 will only be described for its differences relative to the embodiment of FIG. 1.

In this embodiment, emissivity in the infrared of the capsules 350 is improved, thanks to internal walls made of material highly emissive in the infrared range.

In particular, each capsule 350 consists of an outer layer 350C, ensuring the mechanical strength of the capsules, and an inner layer 350D, dedicated more specifically to the emission of electromagnetic radiation in the infrared, towards the bolometric plates.

The outer layers 350C correspond to the description of the capsules given with reference to FIG. 1.

Each inner layer 350D directly covers at least one part of the outer layer 350C, on the interior side of the capsule.

Each inner layer 350D covers in particular, on the interior side of the capsule, the upper wall of the inner layer 350C, and if need be its side walls.

The inner layer 350D has high emissivity in the infrared, greater than that of the outer layer 350C.

The inner layer 350D may comprise, or consist in:
a nitride (in particular titanium nitride TiN, but also a nitride such as: SiN, Si₃N₄, AlN, WN, W₂N), wherein the inner layer can consist for instance in a single nitride or in an alloy comprising a nitride (such as Ti/TiN);
a material based on carbon such as graphite (graphene being preferably excluded);
an oxide such as SiO₂, SiOₓ; etc

This embodiment may be obtained by means of two successive depositions on the sacrificial pads as mentioned above, to deposit firstly the material of the inner layer 350D, then the material of the outer layer 350C.

FIG. 4 schematically illustrates a fourth embodiment of print sensor 400 according to the invention.

The embodiment of FIG. 4 will only be described for its differences relative to the embodiment of FIG. 1.

In this embodiment, the metal layer forming the infrared filter 460 extends all in one piece above several capsules, and is connected to a constant potential, to form a protection with regard to build ups of electrostatic charges.

Charges can build up when a finger is in contact with the contact surface 471 of the print sensor, up to causing an electrostatic discharge.

Electrostatic discharges may, in the long run, damage the print sensor and in particular the bolometric plates.

Here, the metal layer is simply connected to the ground 462, by a via that passes through the intermediate layer 420 and the material of the capsules.

In a variant, the sensor comprises an ancillary metal layer, above the infrared filter(s), dedicated uniquely to protection with regard to electrostatic discharges.

Although the metal filter 460 covers several capsules, preferably it does not fill the space between the capsules, to limit heat exchanges between the capsules.

According to a variant not represented, the metal filter 460 has through openings between the capsules, to further limit heat exchanges between the capsules.

FIG. 5 schematically illustrates a fifth embodiment of print sensor 500 according to the invention.

The embodiment of FIG. 5 will only be described for its differences relative to the embodiment of FIG. 1.

In this embodiment, the capsules 550 are physically separated from each other, without physical contact between them. They are thus thermally and electrically insulated from each other, which improves the contrast of an image of the print obtained by means of the print sensor 500 according to the invention.

Here, the material of the capsules does not extend between the capsules, on the side of the substrate. However, the material of the capsules also extends between the capsules, with the same height and same thickness as their respective upper walls. Trenches 514 extend in this material, between the capsules, to insulate the capsules from each other.

Preferably, the trenches 514 separating the capsules together form a grid consisting of a first series of parallel trenches, secant with a second series of parallel trenches.

In practice, a matrix of capsules physically insulated from each other may be produced by means of the method described above, in which:

the second sacrificial layer is etched everywhere, except around the bolometric plates, and at the emplacements intended to form separating spaces between the capsules, to form sacrificial pads;

the material of the capsules is deposited in the interstices between the sacrificial pads, and above the latter;

the material of the capsules is etched locally to form the orifices 551 in the capsules 550, and the trenches 514 between the capsules; and

the sacrificial pads are removed while going through the orifices 551, respectively the trenches 514.

The sacrificial pads at the emplacements intended to form separating spaces between the capsules may together form a grid, with, in each hole of the grid, a sacrificial pad surrounding a bolometric plate.

This method is particularly advantageous since the separation of the capsules is produced in a same technological step as the etching of the orifices in the capsules.

In a variant, the print sensor only differs from the sensor of FIG. 1 in that the portions of the thermoresistive material between the capsules, on the substrate side, are opened by trenches separating neighbouring capsules.

Here, each capsule is separated from the other capsules. In a variant, the capsules are formed all in one piece in rows of capsules, physically separated from the other rows of capsules.

In the example represented in FIG. 5, each capsule 550 is covered by a separate optical filter 560, physically separated from the other optical filters 560, without physical contact between them.

In a variant, each optical filter may extend all in one piece above one row of capsules, physically separated from the other optical filters extending above another row of capsules.

Whatever the case, as illustrated in FIG. 5, and as in the embodiment of FIG. 1, each bolometric plate is covered by an optical filter 560.

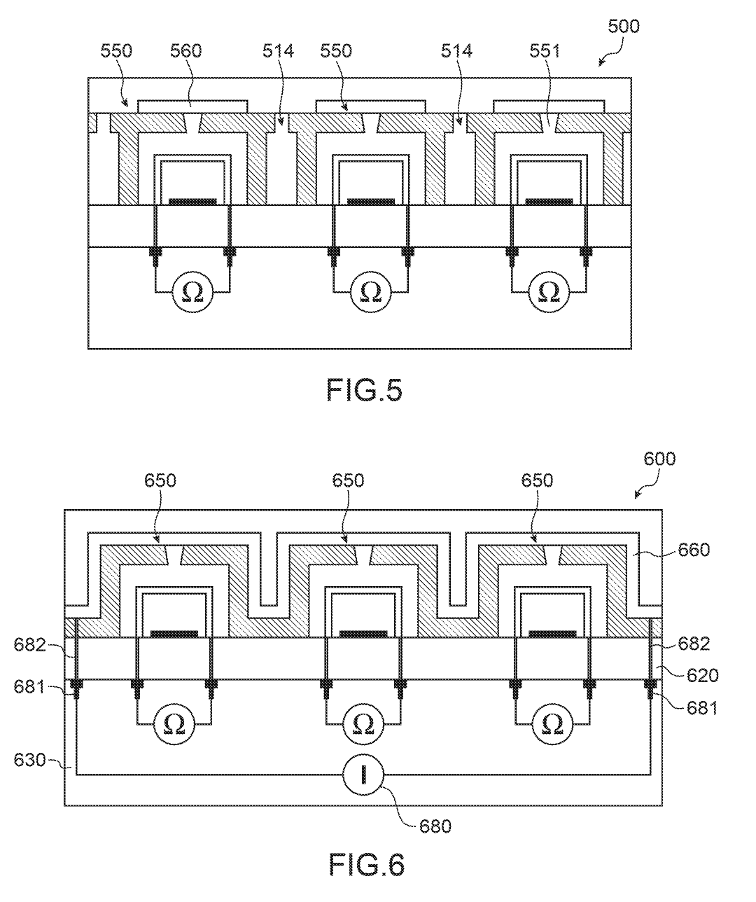

FIG. 6 schematically illustrates a sixth embodiment of print sensor 600 according to the invention.

The embodiment of FIG. 6 will only be described for its differences relative to the embodiment of FIG. 1.

In this embodiment, the infrared filter 660 is a metal layer connected to a current (or voltage) source 680, for the injection of a polarisation current (or a polarisation voltage) suited to heating said metal layer.

Here, the current (or voltage) source 680 is integrated in the substrate 630. The current flows successively in a second connection pad 681, flush with the upper surface of the substrate, then in a via 682, through the intermediate layer 620 and the material of the capsules, then in the metal layer 660, then in another via 682 and another second connection pad 681.

The polarisation current (or the polarisation voltage) heats the metal layer 660, by Joule effect.

This heat is transmitted by conduction to the capsules.

It is thus possible to improve the contrast of the image of the print, and the signal to noise ratio of this image, within the scope of thermal detection of passive type, when the initial temperature of the capsules is too close to the temperature of the finger.

It is also possible to avoid saturation of the sensor, if this difference in temperature is too high.

In practice, it is possible to implement the heating for a second acquisition only, if the first acquisition does not offer sufficient contrast.

It is also possible to use this heating of an optical filter to modify its impedance and thus amplify a mismatch of impedance with a vacuum inside the capsules, by exploiting the thermoresistivity properties of the optical filter.

Here again, as represented by FIG. 6, each bolometric plate is covered by the optical filter 660.

This embodiment may be combined with the embodiment in which the metal infrared filter is connected to a constant potential, to form a protection with regard to build ups of electrostatic charges (see in particular FIG. 4).

For example, the metal infrared filter may be connected to a switch device, to switch between two modes. It is thus possible to connect said filter to a constant potential source, during an initial phase of bringing a print (or other object) into contact with the contact surface of the sensor (first mode). It is then possible to connect said filter to a current or voltage source for the injection of a polarisation current or voltage intended to heat the metal filter (second mode). A presence detector may enable switching from one mode to the other.

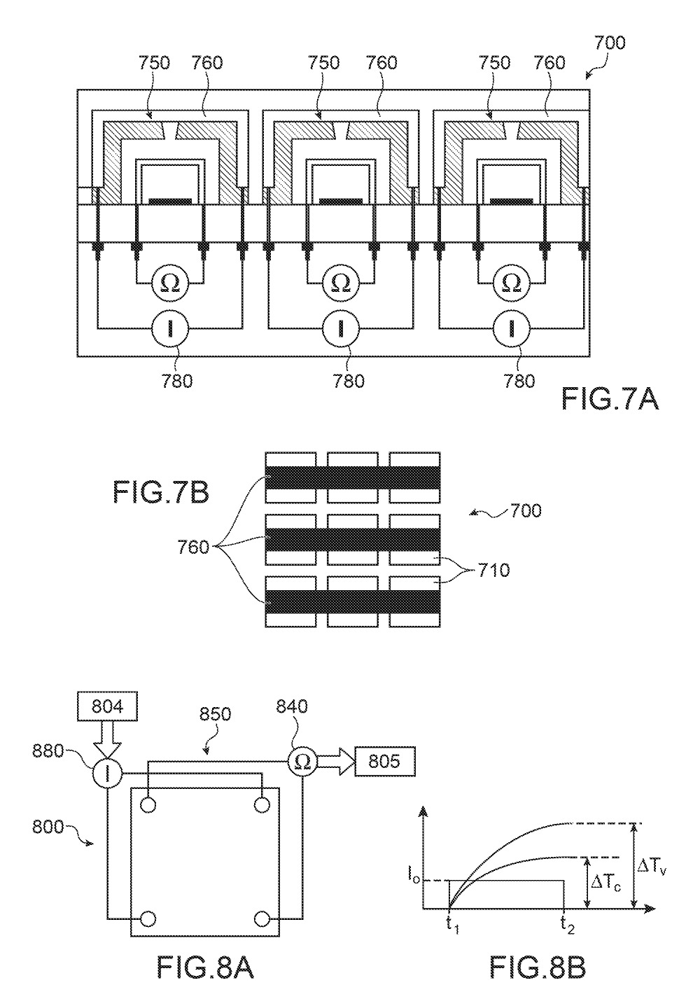

FIGS. 7A and 7B schematically illustrate a seventh embodiment of print sensor 700 according to the invention.

The embodiment of FIG. 7A will only be described for its differences relative to the embodiment of FIG. 1.

Here again, as represented by FIG. 7A, each bolometric plate is covered by an optical filter 760.

In this embodiment, the optical filters together form heating bands.

FIG. 7B shows in a schematic manner the print sensor 700, according to a top view. It may be seen that the capsules 750 are distributed according to a square mesh. They form together a matrix of capsules, in which each capsule receives a bolometer.

The width of the matrix of capsules designates one of its dimensions in a plane parallel to the substrate. It is not necessarily the largest dimension.

The optical filters covering the capsules are here formed by metal bands 760 parallel with each other, which each extend over the whole width of the matrix of capsules. In other words, each metal band 760 covers a row of capsules 750.

Each metal band 760 is connected to a current (or voltage) source 780, of the type of source described with reference to FIG. 6.

Each metal band 760 forms a heating band, to heat the line of capsules situated below.

In operation, all the heating bands are not necessarily actuated at the same time.

This makes it possible to restrict the maximum electrical power to supply to the print sensor 600.

Moreover, it is possible to integrate successively the electrical signals of the different lines of bolometers, and to only heat the heating band above the line of bolometers the signals of which are integrated. A bolometers line is then read, while the signal is integrated on the following line.

The energy consumption of the sensor 600 is thus restricted.

In particular, the electrical signals of the lines of bolometric plates associated with the matrix of capsules are integrated one line after the other, from bottom to top (or from top to bottom). In the same way, the heating bands are activated one after the other, from bottom to top (or from top to bottom), and in a synchronous manner with the integration of the electrical signals of the lines of bolometric plates.

In a variant, each capsule is covered by a separate optical filter, physically separated from the other optical filters, without physical contact between them, and each optical filter may be heated individually.

The heating is optimal, because the heat source, here the optical filter, is situated between the capsules and the finger.

As detailed above, when a finger is laid on the sensor, each capsule exchanges more or less heat with said finger depending on whether it is covered by a ridge or by a valley of the print, the heat exchange modifying the temperature of the capsule and thus the power of the electromagnetic radiation emitted and detected by the bolometric plates.

However, after a certain time, the temperature of the sensor may become homogenous, such that the difference in temperature between a capsule associated with the ridges and a capsule associated with the valleys of the print is reduced. A loss of contrast on the image of the print ensues.

In order to overcome this, it is possible to heat the capsules, in particular through the optical filter situated above.

As detailed above, a heat exchange is going to take place between the finger and the capsules, more or less important depending on whether the capsule is covered by a ridge or by a valley of the print.

In particular, it may be a heat exchange by conduction, when there is direct contact between the tissues of the skin and the contact surface, at the level of the ridges of the print.

In a variant, it is a heat exchange by convection, at the level of the valleys of the print.

Since heat exchange is more efficient by conduction than by convection, the variation in the temperature of each capsule varies, depending on whether it is located under a ridge or under a valley of the print.

By measuring a variation in the electrical resistance associated with a capsule, over a predetermined time interval, it is possible to determine whether it is covered by a ridge or a valley of a finger print.

The heating of the capsules makes it possible to break the thermodynamic equilibrium which can be established within the print sensor, to conserve a contrasted image of the print.

This type of detection may be called “active detection mode”. It uses measurements of variations in electrical resistances, coupled to heating of the sensitive elements.

FIGS. 8A and 8B illustrate in a schematic manner an eighth embodiment of print sensor according to the invention, suited to the implementation of an active thermal type detection.

FIG. 8A schematically shows a capsule 850, according to a top view. The capsule 850 is indirectly heated by a current (or voltage) source 880, which heats the optical filter covering said capsule. The electrical resistance of the bolometric plate, under the capsule 850, is read by electrical resistance reading means 840.

The source 880 is connected to control means 804, to actuate the injection of a current (or a voltage) during a predetermined time interval.

FIG. 8B illustrates a current pulse supplied by the current source 880 (constant current I₀ between the instants t₁ and t₂, and zero otherwise).

This current pulse supplies to the capsule, via the corresponding optical filter, a constant quantity of heat, between the instants t₁ and t₂ (see FIG. 8B).

When the capsule is covered by a valley of the print, heat is transmitted to the finger by convection. The efficiency of this heat transfer is low, such that the temperature of the capsule increases considerably between the instants t₁ and t₂ (variation in temperature ΔTᵥ, see FIG. 8B).

When the capsule is covered by a ridge of the print, heat is transmitted to the finger by conduction. The efficiency of this heat transfer is high, such that the temperature of the capsule increases slightly between the instants t₁ and t₂ (variation in temperature ΔT_{c}<ΔTᵥ).

These variations in temperature correspond to variations in intensity of the electromagnetic radiation emitted towards the bolometric plates, and finally by variations in electrical resistances measured at the level of the bolometric plates.

The means 840 of reading the electrical resistance of the bolometric plate are thus connected to comparison means 805, to measure a variation in the electrical resistance of the bolometric plate between two instants, in particular between the instant of start of heating of the capsule, and the instant of end of this heating, here between t₁ and t₂.

It is possible to convert said variation in electrical resistance into grey levels to form an image of the finger print.

This detection may be implemented with optical filters each associated with a capsule and physically separated from each other, or with optical filters forming together heating bands, as described with reference to FIGS. 7A and 7B, or even with an optical filter formed all in one piece above the whole matrix of capsules.

This detection may also be combined with the synchronous heating and reading of resistances.

The invention is not limited to the examples described, and numerous variants of the embodiments described above could be made without going beyond the scope of the invention.

For example, the capsules may be distributed along a single line of capsules, the finger (respectively the hand) being moved above this line of capsules to detect all of the print. In a variant, it is the linear sensor that is moved relatively to the hand or to the finger, which remain fixed. In this case, the heating of the capsules is not necessarily useful.

1. A sensor of thermal patterns of an object, comprising a contact surface to apply the object to image thereon, sensor comprising:
at least one capsule sealed under vacuum, arranged between a substrate and said contact surface, suited to exchanging heat by conduction with the object to image and to emitting electromagnetic radiation as a function of its temperature;
inside each capsule sealed under vacuum, at least one bolometric plate, suited to converting incident electromagnetic radiation coming from the capsule into heat;
at least one optical filter, to stop electromagnetic radiation in the infrared, each capsule being covered by an optical filter; and
means of reading the electrical resistances of the bolometric plates.

2. The sensor according to claim 1, comprising a plurality of capsules, and wherein a single bolometric plate is arranged inside each capsule.

3. The sensor according to claim 1, wherein each optical filter is made of metal.

4. The sensor according to claim 3, wherein the impedance of each optical filter is at least 50 times less than that of a vacuum inside each capsule.

5. The sensor according to claim 3, wherein each optical filter is electrically connected to a constant potential source.

6. The sensor according to claim 1, wherein each capsule has a cap shape, an upper wall of which is opened by at least one orifice, and the side and upper walls of which cooperate with a lower layer, and an upper layer, to encompass a closed volume.

7. The sensor according to claim 1, wherein the capsules are made of amorphous silicon or an alloy comprising amorphous silicon.

8. The sensor according to claim 1, wherein the capsules comprise:
an outer layer made of amorphous silicon or an alloy comprising amorphous silicon; and
an inner layer, having an emissivity in the infrared greater than that of the outer layer.

9. The sensor according to claim 1, wherein the capsules are separated from each other, without direct physical contact between them.

10. The sensor according to claim 1, wherein the optical filters of different capsules, or lines of capsules, are separated from each other, without direct physical contact between them.

11. The sensor according to claim 1, wherein an optical filter extending all in one piece above several capsules has through openings situated between the capsules.

12. The sensor according to claim 3, wherein each optical filter is connected to a current or polarisation voltage source, for the injection of a current or voltage suited to heating said optical filter.

13. The sensor according to claim 12, comprising control means, configured to actuate said current or voltage source during a predetermined time interval, and wherein the reading means are connected to comparison means, to determine a variation in the electrical resistance of the bolometric plate, between two predetermined instants.

14. A method of using a sensor according to claim 12, wherein the bolometric plates are distributed in lines to form a matrix of bolometric plates, and wherein the optical filters form heating lines, each above a line of bolometric plates, a reading of the electrical resistances of the bolometric plates being conducted line by line, and a heating of the optical filters being also conducted line by line and in a synchronous manner with the reading of the electrical resistances.
